(19) United States
(12) Patent Application Publication
(10) Pub. No.: US 2016/0005906 A1
(43) Pub. Date: Jan. 7, 2016

(54) Optoelectronic Thermal Interfaces for 3-Dimensional Billet Devices, Including Vertical Multijunction Photovoltaic Receivers Using Heat Sinked Anode/Billet/Cathode For High Intensity Beaming and Wireless Power Transmission

(71) Applicants: Chiun-Yen Tung, Kaohsiung City (TW); Mei-huan Yang, Kaohsiung City (TW); Terry Zahuranec, North Olmsted, OH (US); Remigio Perales, Oberlin, OH (US); Te-Chih Huang, Kaohsiung City (TW); Jheng-Syuan Shih, Kaohsiung City (TW); Cheng-Liang Wu, Kaohsiung City (TW); Chin-Wei Hsu, Zhongli City (TW); Mark J. Elting, OSSINING, NY (US)

(72) Inventors: Chiun-Yen Tung, Kaohsiung City (TW); Mei-huan Yang, Kaohsiung City (TW); Terry Zahuranec, North Olmsted, OH (US); Remigio Perales, Oberlin, OH (US); Te-Chih Huang, Kaohsiung City (TW); Jheng-Syuan Shih, Kaohsiung City (TW); Cheng-Liang Wu, Kaohsiung City (TW); Chin-Wei Hsu, Zhongli City (TW); Mark J. Elting, OSSINING, NY (US)

(73) Assignee: MH Solar Co. LTD., Kaohsiung City (TW)

(21) Appl. No.: 14/324,040

(22) Filed: Jul. 3, 2014

(51) Int. Cl. H01L 31/052; H01L 31/18; H01L 31/047

(52) U.S. Cl. CPC H01L 31/0521; H01L 31/047; H01L 31/18

(57) ABSTRACT

Thermal, electrical and/or optical interfacing for three-dimensional optoelectronic devices, such as semiconductor device billets, allows high intensity operation, such as for receiving and transducing extremely high intensity light shined onto a small surface semiconductor optoelectronic device such as a photovoltaic receiver or cell, transducer, waveguide or splitter. This allows high intensity energy transfer for beam receiving, signal acquisition, and beam or signal generation for high intensity power beaming and wireless power transmission. Preferred embodiments include three-dimensional photovoltaic receiver billets capable of receiving thousands of suns intensity or high intensity laser light for power conversion, such as by using edge-illuminated vertical multijunction photovoltaic receivers. Heat sink holding structures assist in thermal and electromagnetic communication with opposing billet surfaces.

### TECHNICAL FIELD

This invention relates to thermal and electrical/optical interfacing for three-dimensional optoelectronic devices, such as semiconductor device billets, to allow high intensity operation, such as for receiving and transducing extremely high intensity light shined onto a small surface semiconductor optoelectronic device such as a photovoltaic receiver or cell, transducer, waveguide or splitter. The emphasis in this disclosure shall be on use of the instant teachings for energy transfer, beam receiving, signal acquisition, and beam or signal generation in, out and about a three-dimensional optoelectronic device, three-dimensional photovoltaic receiver billet, or other transducing material body. Preferred embodiments include edge-illuminated vertical multijunction photovoltaic receivers operating under hundreds or thousands of suns intensity.

### BACKGROUND OF THE INVENTION

The field of energy conversion is undergoing large changes as direct energy conversion processes such as photovoltaic conversion are becoming less costly and are meeting higher engineering benchkmarks that allow for large scale implementation and for new applications in disparate fields such as robotics and aerospace industries. Engineers have long contemplated using high intensity energy conversion, such as high intensity photovoltaic conversion to make possible remote signal and/or power transmission using lasers or flux beams in conjunction with concentrated solar power (CSP), wireless power transmission (WPT), and high intensity laser power beaming (HILPB), such as for energizing or recharging power supplies on unmanned aerial vehicles (UAVs) or drones.

Among the many references discussing these applications are US Patent Publication 2008/0245930 to Nayfeh et. al., “High Intensity Laser Power Beaming for Space and Terrestrial Applications,”—and also—Raible, Daniel E.; Fast, Brian R.; Dinca, Dragos; Nayfeh, Taysir H. and Jalics, Andrew K., Comparison of Square and Radial Geometries for High Intensity Laser Power Beaming Receivers, NASA/TM—2012-217255, ISBN 978-1-4244-9686-0; both hereby incorporated by reference herein in their entirety.

The success of these new initiatives very much hinges upon device limitations—typically semiconductor device limitations—and engineering constraints. For illustrative purposes, and also to inform regarding preferrred embodiments, the instant teachings can be applied to photovoltaic receivers and cells.

Photovoltaic receivers, and photovoltaic energy conversion generally, typically make use of the photovoltaic effect. Solar cells use this effect inside what are usually traditional solid-state semiconductors, formed by single or multiple lattices of semiconductor crystals with two alternating type of dopants—those doped with n-type impurities to form n-type semiconductors, which provide a free population of conduction band electrons, and those doped with p-type impurities to form p-type semiconductors, which add what are called electron holes. Electrons flow across the lattice boundaries to equalize the Fermi levels of the two differently doped materials. This results in what is called charge depletion at the interface, called the p-n junction, where charge carrier populations are depleted or accumulated on each side.

Sunlight, for example, can cause photo excitation of electrons on the p-type side of the semiconductor lattice, which can cause electrons from a lower-energy valence band to pass into a higher-energy conduction band. These electrons, after subtracting various energy and charge carrier losses, can do work across an electrical load as they flow out of the p-type side of the lattice to the n-type side. The result is a known and mature direct energy conversion process which offers relatively high conversion efficiencies, especially if light of selected wavelengths is selected for absorption.

Recently, energy efficiencies have gone up via a newer type of lattice construction using multiple junctions which are custom fabricated using different semiconductor materials and dopants to operate efficiently for selected wavelenegths. Development of these and other enhanced photovoltaic technologies, such as vertical multijunction (VMJ) photovoltaic cells, offer promise for concentrated solar photovoltaics. In a photovoltaic device, each semiconductor or other material can create a p-n junction or interface that produces charge carrier current in response to a select distribution of wavelengths of light. Such multijunction photovoltaic cells provide optimal light-to-electricity conversion at multiple or select wavelengths of light, which can increase overall energy conversion efficiency. Traditional single-junction cells have a maximum theoretical efficiency of 34%. Theoretically, multijunction photovoltaics have a maximum theoretical efficiency in excess of 50% under highly concentrated sunlight. In addition, high voltage silicon vertical multijunction photovoltaic solar cells made using recently developed fabrication techniques are ideally suited for beam-split concentrated light applications, as they are capable of conversion of light intensities of tens or hundreds or thousands of suns intensity AM1.5.

Structurally, VMJ cells are an integrally bonded series-connected array of miniature silicon vertical unit junctions. They offer design simplicity, low cost, and an innovative edge-wise entry for light that allows for easy and controlled absorption and conversion at the high energy levels produced by hybrid concentrated solar power. Their higher per-unit cost relative to single junction photovoltaics can be more than justified by their ability to handle and convert concentrated solar power and the high voltage they produce is more easily handled electrically by power conditioning systems that prepare the photovoltaic power for use in an application, such as for remote power transfer.

Vertical multijunction photovoltaic receivers can be used to great advantage in hybrid thermal/photovoltaic systems, and for laser-assisted or beam-assisted remote power transfer. They are easily fabricated and assembled into units that produce high voltage, low current producers that offer myriad advantages, as discussed in IEEE and other proceedings, such as—B. L. Sater, N. D. Sater, “High voltage silicon VMJ solar cells for up to 1000 suns intensities,” Photovoltaic Specialists Conference, 2002. Conference Record of the Twenty-Ninth IEEE, Publication Date 19-24 May 2002, pgs. 1019-1022 ISSN 1060-8371, ISBN 0-7803-7471-1—hereby incorporated by reference herein in its entirety.

As with all semiconductor devices, thermal considerations can be critical. With applications contemplated that result in energy transfer intensities equivalent to more than 1000 suns, exposure levels can approach and surpass one million watts/meter ̂2 on the surface of a semiconductor device. This high intensity can cause meltdown or drops in performance. In many particular photovoltaic applications at an illustrative base temperature of 100 C during operation, each 10 C increase in temperature can results in an approximately three percent reduction in energy conversion performance, and high temperatures reduce operating life. So while it is true that high voltage photovoltaic receivers such as vertical multijunction photovoltaic receivers are now the subject of intense research and development efforts worldwide, their potential in meeting long known engineering requirements is promising but still threatened. There are problems in certain cases with diffusion processes degrading device dynamics, and the thermal loads for large energy transfer or flux-receiving optoelectronic devices, such as three-dimensional optoelectronic device billets, can cause damage from high temperature operation. Specifically, for output devices, such as the three-dimensional optoelectronic output device billets illustratively included in this disclosure that would include high power semiconductor lasers, the possibility of catastrophic optical damage (COD), or catastrophic optical mirror damage (COMD), represents a failure mode of high-power semiconductor lasers that can afflict devices when the operative semiconductor junction is overloaded thermally, such as by exceeding its power density and absorbing excessive produced light. This can produce ill effects such as melting, recrystallization, and defect production in and around the semiconductor material at the facets of the laser.

Prior art attempts at thermal management fall short to insure problem-free operation of semiconductor devices. Prior art devices often attempt to solve this problem using thermally conductive pathways such as found in U.S. Pat. No. 7,985,919 to Roscheisen et al. where known heat sink materials are simply laid out like a bed underneath the semiconductor device in question, sometimes supplemented by external features like fins. A whole array of materials is often enlisted in this effort to conduct away heat. But even with known heat sink materials such as stainless steel, aluminum, copper, aluminum, and other known materials exhibiting excellent heat conduction characteristics, they are no match for high intensity beam handling applications where a 2×2 cm device can be receiving in excess of 400 watts luminous power, with thermal transfer on the order of about 1.000 W/cm ° C. or greater being limited by spatial access and thermal diffusive efficiency.

One objective of the instant invention is to provide a novel arrangement for thermal and optoelectronic interfacing and mounting for all manner of three-dimensional optoelectronic device billets. Another objective is to provide for successful, sustained operation of three-dimensional optoelectronic device billets, three-dimensional photovoltaic receiver billets, and three-dimensional optoelectronic output device billets under high intensity operation that would otherwise damage them or reduce their effectiveness, overall efficiency, and service lifetimes.

### SUMMARY OF THE INVENTION

The invention allows for high intensity energy conversion using a flux source-receiving body such as a three-dimensional optoelectronic device billet, and does not require the use of multiple cooled plates, or the like, but rather a single set of first and second opposing billet surface interfaces. The invention includes:

An optoelectronic holding structure for receiving and communicating with a three-dimensional optoelectronic device billet, the optoelectronic holding structure comprising:

a heat sink holding structure so formed, sized, shaped, and positioned to surround at least partially the three-dimensional optoelectronic device billet, the three-dimensional optoelectronic device billet comprising two opposing first and second billet surfaces;
the heat sink holding structure further formed to comprise opposing first and second heat sink surfaces so sized, shaped, positioned and oriented to be in direct thermal communication with the three-dimensional optoelectronic device billet at least partially via contact with some portion of a corresponding one of the opposing first and second billet surfaces;
the heat sink holding structure additionally so formed to comprise at least one optoelectronic feed in optoelectronic communication with the three-dimensional optoelectronic device billet.

The optoelectronic feed can comprise an electrical feed of at least one of an anode and a cathode in corresponding electrical communication with the three-dimensional optoelectronic device billet.

Alternatively, the optoelectronic feed can comprise an electrical feed with at least a portion of the first heat sink surface comprising one of an anode and a cathode; and at least a portion of the second heat sink surface comprising the other one of the anode and the cathode; the anode and the cathode each formed to be in corresponding electrical communication with the three-dimensional optoelectronic device billet.

The heat sink holding structure can comprise first and second at least somewhat mating separable portions, each so formed, sized and shaped to be proximate the opposing first and second heat sink surfaces, respectively, and these at least somewhat mating separable portions of the heat sink holding structure can be so formed and positioned to be substantially electrically insulated from one another via an air gap, a fluid gap, or an insulator.

The heat sink holding structure can further comprise a receiver waveguide formed proximate an entry side of the three-dimensional optoelectronic device billet. Cooling passages can be provided inside the heat sink holding structure to allow fluid heat transfer with at least one of the first and second heat sink surfaces. The cooling passages can alternatively be formed inside the three-dimensional optoelectronic device billet to allow fluid heat transfer with the billet, with thermal access to protruding extended portions of the billet so formed to dissipate thermal energy via any of conduction transfer, convection transfer, and radiational transfer.

The heat sink holding structure can be so formed to allow beam access to the three-dimensional optoelectronic device billet, and can be further formed to allow beam access to the three-dimensional optoelectronic device billet, and receiving of at least one of a multi-directional input beam spanning two orthogonal directions and a multi-directional input beam in a receptor plane spanning more than two orthogonal directions.

The three-dimensional optoelectronic device billet can comprise at least one of a photovoltaic receiver and a vertical multijunction photovoltaic receiver.

Alternatively, the invention can comprise a photovoltaic receiver system for receiving a high intensity beam, the photovoltaic receiver system comprising:

a three-dimensional photovoltaic receiver billet comprising opposing first and second billet surfaces;
an optoelectronic holding structure for receiving and communicating with the three-dimensional photovoltaic receiver billet, the optoelectronic holding structure further comprising a heat sink holding structure so formed, sized, shaped, and positioned to surround at least partially the three-dimensional photovoltaic receiver billet;
the heat sink holding structure further formed to comprise opposing first and second heat sink surfaces each so sized, shaped, positioned and oriented to be in direct thermal communication with the three-dimensional photovoltaic receiver billet at least partially via contact with some portion of a corresponding one of the opposing first and second billet surfaces;
and with the heat sink holding structure additionally so formed to comprise an anode and a cathode each so positioned and formed to allow ohmic contact with a corresponding one of the opposing first and second billet surfaces.

An anode and a cathode can be each formed on a corresponding one of the first and second heat sink surfaces.

Another embodiment of the invention can comprise a thermal and electrical interface for a high intensity optoelectronic output device, the thermal and electrical interface comprising:

a three-dimensional optoelectronic output device billet comprising opposing first and second billet surfaces;
an optoelectronic holding structure for thermal and electrical communication with the three-dimensional optoelectronic output device billet, the optoelectronic holding structure further comprising a heat sink holding structure so formed, sized, shaped, and positioned to surround at least partially the three-dimensional optoelectronic output device billet;
with the heat sink holding structure further formed to comprise opposing first and second heat sink surfaces, each so sized, shaped, positioned and oriented to be in direct thermal communication with the three-dimensional optoelectronic output device billet at least partially via contact with some portion of a corresponding one of the opposing first and second billet surfaces;
with the heat sink holding structure additionally so formed to comprise an anode and a cathode each so positioned and formed to allow ohmic contact with a corresponding one of the opposing first and second billet surfaces.

The three-dimensional optoelectronic output device billet can comprise a light-emitting diode, a solid state diode laser, a three-dimensional laser, a vertical-external-cavity surface-emitting-laser, a vertical cavity surface-emitting laser, or a future output device.

The invention can include various methods, such as a method for establishing a thermal and electromagnetic interface with a three-dimensional optoelectronic device billet, the method comprising:

[1] surrounding at least partiallythe three-dimensional optoelectronic device billet with a heat sink holding structure;
[2] communicating thermally with two opposing first and second billet surfaces on the three-dimensional optoelectronic device billet with the heat sink holding structure via at least partial direct thermal contact therebetween; and
[3] communicating optoelectronically with the three-dimensional optoelectronic device billet Alternatively, the invention can comprise a method for receiving and photovoltaic conversion of a high intensity beam, the method comprising:
[1] receiving the high intensity beam on a three-dimensional photovoltaic receiver billet that comprises opposing first and second billet surfaces and that is at least partially surrounded by a heat sink holding structure;
[2] communicating thermally with the two opposing first and second billet surfaces on the three-dimensional photovoltaic receiver billet using the heat sink holding structure via at least partial direct thermal contact therebetween; and
[3] communicating electrically via the three-dimensional photovoltaic receiver billet via separate corresponding polarity ohmic contacts with each of the opposing first and second billet surfaces.

Additionally, the high intensity beam can be modulated according to any known communications protocol.

Finally, the invention can also include a method for operating a three-dimensional optoelectronic output device billet to produce a beam, the method comprising:

[1] communicating electrically with the three-dimensional optoelectronic output device billet via separate corresponding polarity ohmic contacts with each of opposing first and second billet surfaces located thereupon;
[2] communicating thermally with the two opposing first and second billet surfaces on the three-dimensional optoelectronic output device billet using a heat sink holding structure via at least partial direct thermal contact therebetween; and
[3] allowing the beam produced by the three-dimensional optoelectronic output device billet to pass outward from the heat sink holding structure—and in a similar manner, the outgoing beam can be modulated according to a communications protocol.

### BRIEF DESCRIPTION OF THE DRAWINGS

FIG. 1 shows an oblique surface schematic view of a prior art edge-illuminated vertical multijunction photovoltaic receiver array, showing schematic thermal flow;

FIG. 2 shows an oblique surface schematic view of a individual cell from a prior art vertical multijunction photovoltaic receiver array;

FIG. 3 shows a cross-sectional schematic diagram of a prior art edge-illuminated vertical multijunction photovoltaic receiver array, showing mounting and schematic thermal flow;

FIGS. 4-6 show oblique surface views of three illustrative three-dimensional optoelectronic device billets that can be used to practice the invention, with incident beams impinging upon billet entry sides;

FIGS. 7-8 show oblique partial cut-out surface views of optoelectronic holding structures, depicting illustrative three-dimensional optoelectronic device billets interfaced thermally and optoelectronically using heat sink holding structures according to the invention, with FIG. 8 illustratively shown partially cut out;

FIG. 9 shows an oblique partial cut-out surface view similar to that shown in FIG. 8, for an alternate embodiment of the invention, showing thermal flow and action of a receiver waveguide plane upon an incident beam;

FIG. 10 shows an oblique partial cut-out surface view similar to that shown in FIG. 9, for an alternate embodiment of the invention and showing one separable mating portion of a heat sink holding structure interfacing with an illustrative three-dimensional photovoltaic receiver billet in the shape of a triangular prism, and showing thermal flows and one illustrative optoelectronic feed;

FIG. 11 shows the oblique partial cut-out surface view similar to that shown in FIG. 10, with the illustrative three-dimensional photovoltaic receiver billet removed for clarity, showing an illustrative second heat sink surface on the heat sink holding structure and able to conduct thermal flow and provide an anode feed;

FIG. 12 shows the oblique partial cut-out surface view of a complete optoelectronic holding structure 101 according to the invention, showing joined together separable heat sink holding structure mating portions that are mutually electrically isolated, with a beam impinging upon a three-dimensional optoelectronic device billet;

FIG. 13 shows an oblique partial cut-out surface view similar to that shown in FIG. 9, with an illustrative three-dimensional optoelectronic output device billet that can produce an output beam illustratively shown when thermally and optoelectronically interfaced using the teachings of the instant invention using a heat sink holding structure;

FIGS. 14-15 show oblique partial cut-out surface views of a three-dimensional optoelectronic device billet according to the invention, and showing illustrative internal and external cooling systems.

### DEFINITIONS

The following definitions shall be used throughout:

Beam—shall comprise any energy transfer or beam of electromagnetic radiation such as light, or electromagnetic flux, such as electrical and/or magnetic flux or other electromagnetic excitation or thermal excitation from any source used functionally to practice the instant invention. A beam can be so oriented to energize at least partially a billet, such as a three-dimensional optoelectronic device billet, a three-dimensional photovoltaic receiver billet, or a three-dimensional optoelectronic output device billet as taught herein. A beam can include radiation not confined to a collimated, coherent or pencil-like beam shape, or not confined to impingement onto the billets illustratively shown, and therefore can include flux swaths or light spots larger than the receiver in the illustrative embodiments that are shown and described here for clarity.

Billet shall be defined broadly and can comprise any electrical, electronic, optoelectronic, optical, glass, crystalline, quasi-crystallineor ceramic device or material body; or any transducer, sensor, memory device, photovoltaic cell, photovoltaic array, or other component which is so formed to comprise at least one electrical, or optoelectronic feed, and is capable of comprising by structural form two heat sinking surfaces on two separate opposing surfaces. A billet can include any and all associated reflective, refractive, optical, electrical, surface components, such as lenses or other desired device components without departing from the invention.

Communicating—shall by context include communication for signal transmission as well as power transmission, delivery of a thermal fluid or coolant, thermal or heat flow, electrical currents, electromotive force, optical flux or any electromagnetic flux, including varying magnetic fields.

Flux shall refer to electromagnetic radiation, including all forms of light of all frequencies. energy flux in the general sense of the word, flux that allows transmission of power or a signal—and can include radiative flux, heat flux, particle flux, electromagnetic or any power flux, such as a Poynting flux.

Heat sink surface—shall denote any surface or separable surface, or surface existing in a gel, liquid, or fluid format, that is so formed, shaped, positioned, oriented and maintained to effect thermal transfer of energy to or from a billet according to the invention.

Opposing surface shall, in the specification and appended claims and associated description, denote a surface that is spatial separated from and is either parallel or non-parallel with respect to another such surface, and can support thermal communication with a heat sink surface and an optoelectronic feed such as an anode or cathode.

Optoelectronic device shall include any billet as defined in this specification, and thus shall include passive devices such as crystals, such as a ruby crystal.

Optoelectronic feed shall denote any or both of electrical contacts or the equivalent; and optical waveguides or feedthroughs that are so formed to allow receiving, acquisition, or output from a billet.

Photovoltaic receiver—shall denote any conversion device using the Photovoltaic Effect, Photoelectric Effect, or other phenomena to convert incident light, such as solar light, laser light, or infrared light, to an electromotive force employed to drive electric charge carriers, negative and/or positive, and can in preferred embodiments, include vertical multijunction photovoltaic cells or heterostructures designed to produce high conversion efficiency.

Plane/planar—shall include surfaces or components or material bodies that are merely substantially planar, but may possess curved surfaces, small surface features, holes, spikes and other topographically anomalous or secondary features.

Receiver Waveguide shall denote any set of planar surfaces, curved surfaces, or any other surfaces so formed to operate, upon impingement of electromagnetic radiation or flux or any beam, to effect channeling, homogenization, concentration or intensifying onto, about, or into a billet or receiver according to the invention, and shall include any and all reflective, refractive, optical, or electrical components, or surface lenses or similar components, or other device components that accomplish same.

Signal—shall include, throughout the specification and appended claims, any and all signals for any purpose, using any carrier frequency, communication protocol, digital protocol or medium, including when a three-dimensional optoelectronic output device billet produces a beam that is intentionally modulated according to a communications protocol to convey information.

Three dimensional—shall characterize any optoelectronic component used according to the instant invention where first and second opposing billet surfaces of that optoelectronic component do not include a surface used primarily for non-thermal optoelectronic input, output, or communication.

Vertical Multijunction Photovoltaic Cell/Receiver—shall in this disclosure and in the appended claims denote any Multijunction Photovoltaic Cell or device so constructed, and formed, including material formulation, to comprise at least two substantially planar p-n junctions or interfaces or the charge carrier functional equivalent, and is further constructed, shaped and finished to allow disposition for light entry substantially parallel to, or at least at an acute angle with respect to at least one set of those planar junctions. This is in contrast to known single junctions photovoltaic cells or receivers.

### DETAILED DESCRIPTION

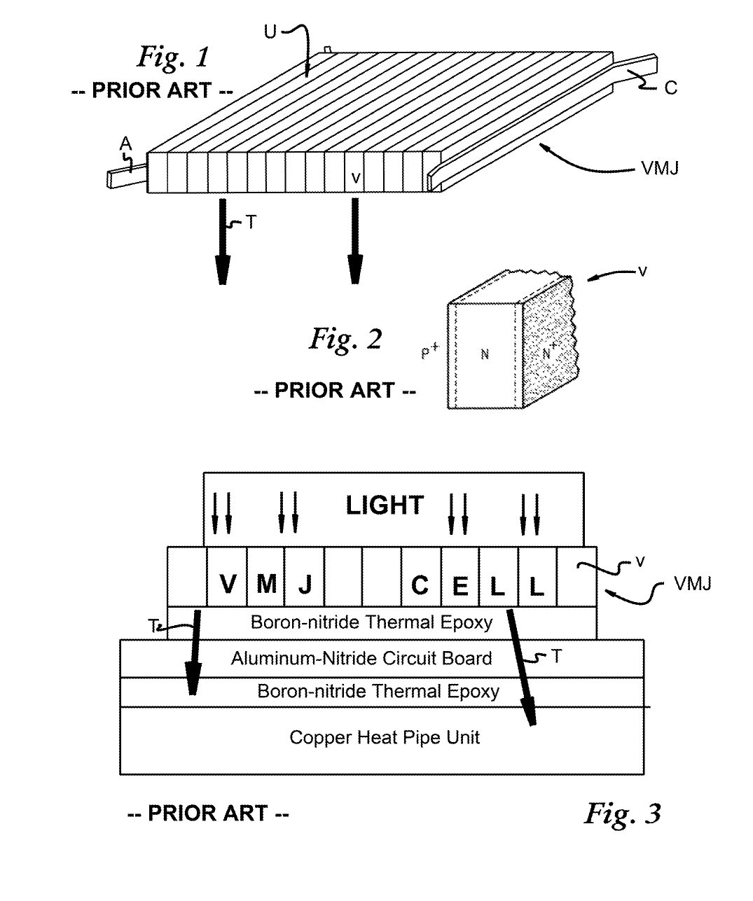

Now referring to FIG. 1, an oblique surface schematic view of a prior art edge-illuminated vertical multijunction photovoltaic receiver array is shown. As discussed in the above cited references incorporated herein in their entirety, vertical multijunction photovoltaic receiver VMJ as shown comprises a series of ganged or fused together individual cells v that are disposed to allow that an entry side U can exposed to an incoming beam, such as concentrated sunlight, a laser beam or other energy-containing flux as defined under the term, beam, in the Definitions section. FIG. 2 shows an oblique surface schematic view of a individual cell from the prior art vertical multijunction photovoltaic receiver array illustratively shown in FIG. 1. As marked, P+, N, and N+—collectively known in industry as P+NN+, refers to heavy extrinsic doping, such that in silicon, for example, the n+ and p+designations refer to doping that is sufficient to cause bulk resistivity in the range of milliOhm-cm. This is in contrast to resistivity in the range of Ohm-cm for intrinsic semiconductors.

The optoelectronic feed to vertical multijunction photovoltaic receiver VMJ of FIG. 1 is a dual, cross-device feed comprising an anode A and a cathode C as shown. As photovoltaic energy conversion under high intensity light occurs, a relatively large schematically shown thermal flow T flows out of the device, shown downward on the page.

This substantial attempted thermal loading is addressed in prior art structures in a way that is typified by the prior art edge-illuminated vertical multijunction photovoltaic receiver array shown as a cross-sectional schematic diagram in FIG. 3, where thermal mounting and schematic thermal flow T are shown. As can be seen, thermal flow T travels essentially in one overall direction, across the base of the vertical multijunction cell shown in the figure, where in order of passage, the thermal flow T traverses and conducts through known layers, shown illustratively as a boron-nitride thermal epoxy, followed by an aluminum-nitride circuit board, which in turn is supported by another layer of boron-nitride thermal epoxy in turn in direct thermal contact with a plurality of copper heat pipe units or the equivalent. These thermal management material selections are known by those skilled in the semiconductor device arts and have limitations that do not allow successful deployment of the three-dimensional optoelectronic device billets served by the instant invention.

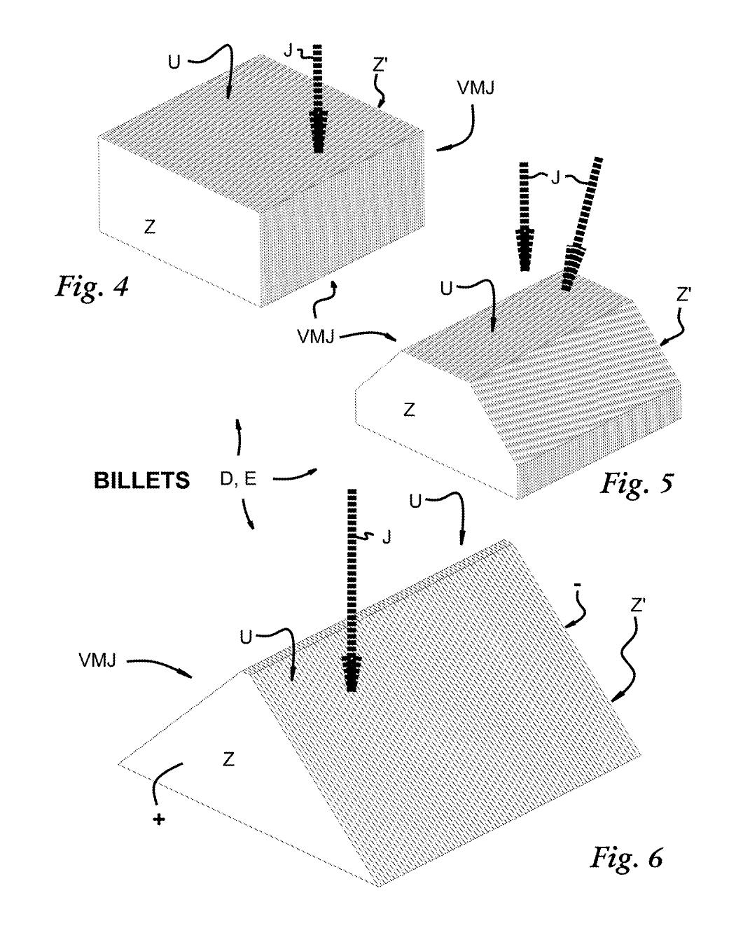

Now referring to FIGS. 4-6, oblique surface views of three illustrative three-dimensional optoelectronic device billets that can be used to practice the invention are shown, with incident beams J impinging upon billet entry sides U. These billets shown are defined more generally in the Definitions section and are merely illustrative and also serve to represent with clarity and simplicity the emphasis in this disclosure upon photovoltaic receivers and vertical multijunction photovoltaic receivers, but shall not limit the scope of the appended claims. As can be seen, FIG. 4 shows a rectangular billet made from a plurality of planar individual wafers or cells, while FIG. 5 shows a similar stack made from trapezoidal shapes pieces, and while FIG. 6 shows a billet in the shape of a triangular prism. The shapes of the optoelectronic or vertical multijunction photovoltaic receiver billets can meet fabrication objectives and/or can enhance edge-illumination light entry. This can allow maximizing light gathering properties based on the design of wave guide receivers, as described below. Each of the three-dimensional optoelectronic device billet D and/or three-dimensional photovoltaic receiver billet E comprises a first opposing billet surface Z and a second opposing billet surface Z′ which are at opposite ends of the stacks of wafers or cells, but the term, opposing surfaces, as defined in the Definitions section shall be controlling. In the three-dimensional photovoltaic receiver billet shown in FIG. 6, first opposing billet surface Z is shown as a surface which carries a positive charge (+), while second opposing billet surface Z′ is shown carrying a negative charge (−), which result from the photovoltaic process across series-connected individual photovoltaic cells.

Fabrication and operation of these vertical multijunction photovoltaic receivers is known in the art. For example, 40 diffused p+nn+silicon wafers of 250 microns thickness can be metallized, stacked and alloyed together to form a multi-layer stack that is 1 cm high. This stack of diffused wafers, when appropriately cut, will yield around 1000 VMJ cells of 1 cm×1 cm×0.05 cm size, each containing 40 series connected unit cells for high voltage operation. Exposed silicon surfaces are etched in a known manner to remove saw damage and passivated with a known anti-reflection coating applied to the illuminated side.

In this way, a 2 cm×2 cm vertical multijunction photovoltaic receiver can be fabricated that generates 80-100 volts under intense light. This can generate 200 watts at 2 amps. In a conventional photovoltaic cell, that same power might require upwards of 180 amps, which can be very problematic for power management.

Only simple billets are shown for clarity. Those skilled in the art of fabrication of optoelectronic devices can supplement the structures shown with associated components, including side reflectors, lenses or other refractive elements, sensors, and collimators and the like, without departing from scope of the invention as expressed in the appended claims.

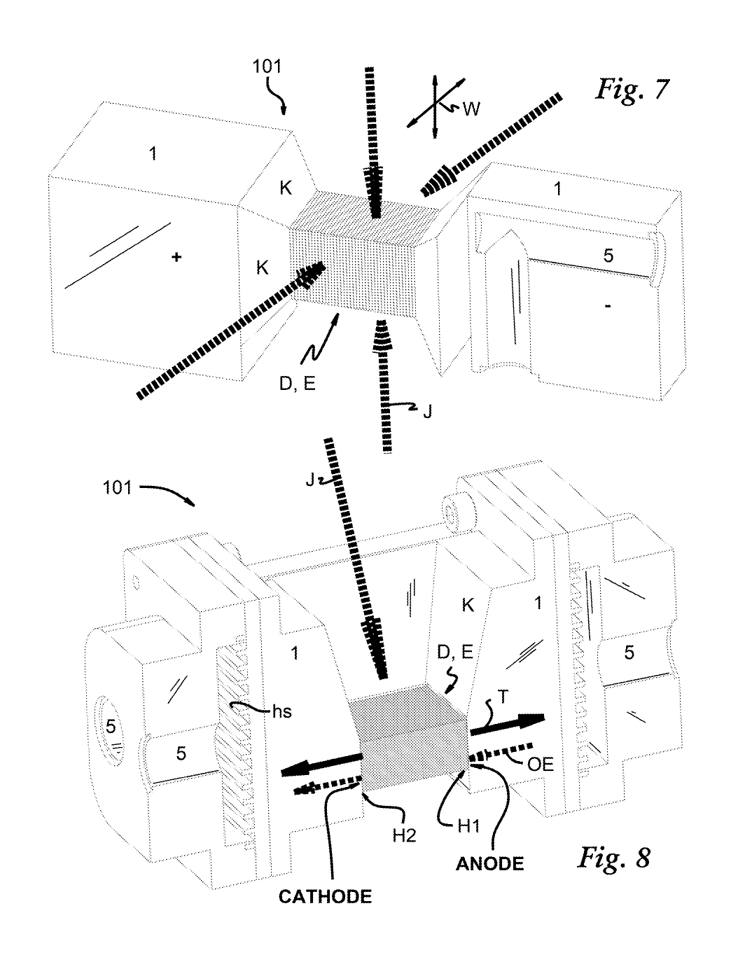

Now referring to FIGS. 7-8, oblique partial cut-out surface views are shown of optoelectronic holding structures, depicting illustrative three-dimensional optoelectronic device billets interfaced thermally and optoelectronically using heat sink holding structures according to the invention, with FIG. 8 illustratively shown partially cut out. FIG. 7 shows an extremely simple embodiment of the invention, whereby a simple three-dimensional optoelectronic device billet D or three-dimensional photovoltaic receiver billet E is interfaceably held as part of a optoelectronic holding structure 101 that comprises two heat sink holding structures 1 illustratively shown that are expressly formed in a preferred manner to allow beam access similar to that illustratively shown by beams J. Specifically shown in FIG. 7 are four representative beams J that are depicted illustratively to lie in a receptor plane W as shown, allowing for multi-directional input beam spanning at least two orthogonal directions and preferably allowing a multi-directional input beam in a receptor plane (W) spanning more than two orthogonal directions for up to 360 degree beam access.

Each of the heat sink holding structures 1 is so formed, sized, shaped, and positioned to surround at least partially the three-dimensional optoelectronic device billets D/E, and each heat sink holding structure 1 is further formed to comprise respective opposing first and second heat sink surfaces (shown in FIG. 8 as H1, H2) that are in turn so sized, shaped, positioned and oriented to be in direct thermal communication with three-dimensional optoelectronic device billet D or three-dimensional photovoltaic receiver billet E at least partially via contact with some portion of the corresponding opposing first and second billet surfaces Z and Z′ as shown in FIGS. 4-6. This allows substantial thermal flow T as shown.

In this preferred embodiment, at the same two first and second opposing billet surfaces, namely, first opposing billet surface Z and second opposing billet surface Z′ as previously shown explicitly, also find an optoelectronic interface (shown, OE) in that first heat sink surface H1 and second heat sink surface H2 comprise, respectively, an anode A and a cathode C (shown, ANODE, CATHODE) which can receive the electromotive force and currents generated by the billet under illumination.

The body of heat sink holding structure 1 can be formed from copper or other known thermally conductive materials, and can comprise a heat sink hs as shown, as well as conventional cooling in the form of internal cooling passages 5 as shown, which can pass through heat sink holding structure 1 and allow a cooling medium to service heat sink hs. The left and right halves of optoelectronic holding structure 101 can be electrically isolated from one another, such as via of an air gap, a fluid gap, and a known insulator.

The body of each heat sink holding structure 1 can be formed to include one or more features that establish receiver waveguide K, which serves to channel, homogenize, concentrate, or intensify incoming beam J onto, about, or into three-dimensional optoelectronic device billet D or three-dimensional photovoltaic receiver billet E. This can be very useful when the invention is used to receive one or more laser light inputs, depending on the received TEM (Transverse Electromagnetic Mode) or light brightness profile.

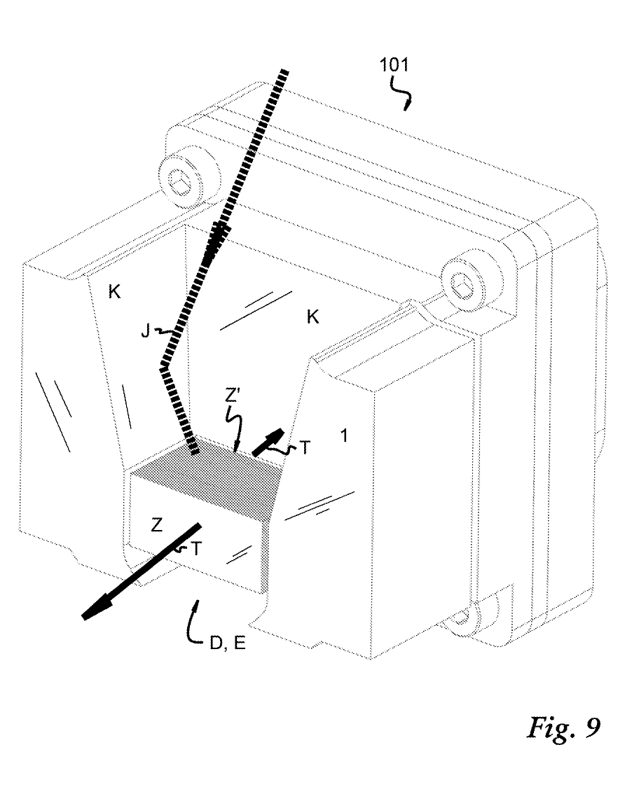

Now referring to FIG. 9, an oblique partial cut-out surface view similar to that shown in FIG. 8, is shown for an alternate embodiment of the invention, showing thermal flow T and action of a receiver waveguide K, such as a reflective plane in the manner shown, which helps to homogenize and collimate in an incoming beam J onto three-dimensional optoelectronic device billet D or three-dimensional photovoltaic receiver billet E. First and second opposing billet surfaces Z and Z′ are shown explicitly in this figure.

As mentioned below, receiver waveguide K like the surfaces of the heat sink holding structure 1, can be fabricated using surface treatments to enhance thermal conductivity, target high reflectivity to desired light wavelengths, and have thermal expansion coefficients that promote structural longevity and problem-free operation.

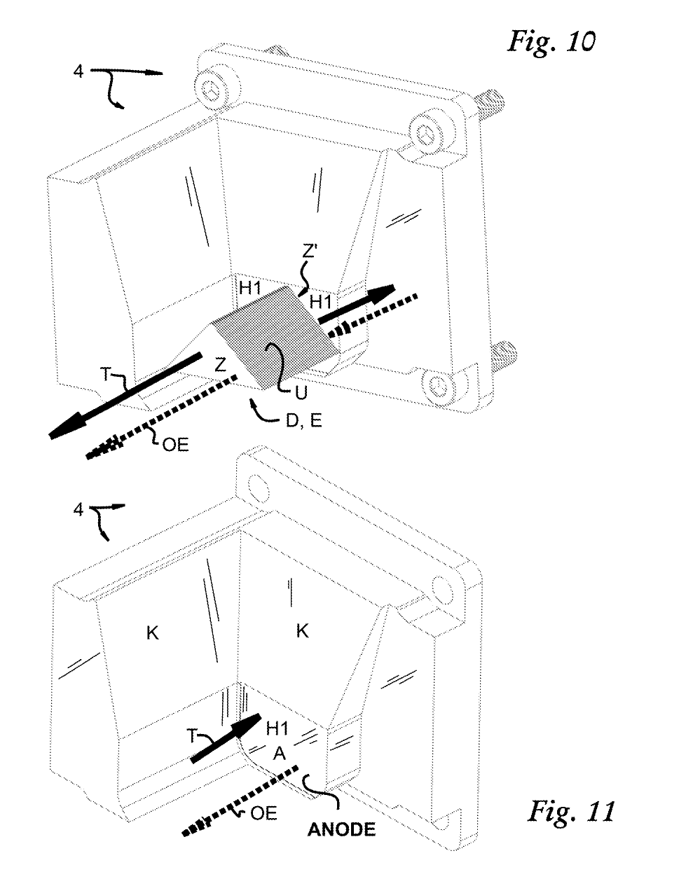

Now referring to FIG. 10, an oblique partial cut-out surface view similar to that shown in FIG. 9, is shown for an alternate embodiment of the invention and showing one separable mating portion 4 of a heat sink holding structure interfacing with an illustrative three-dimensional photovoltaic receiver billet in the shape of a triangular prism, and showing thermal flow T and one illustrative optoelectronic feed. As light enters entry side U, optoelectronic feed OE carries off charge carriers under electromotive force from photovoltaic conversion. Specifically, at second opposing billet surface Z′, a cathode established on heat sink holding structure 1 at first heat sink surface H1 is operative, while substantial thermal flow T is conducted.

This provides a powerful cross-array cooling which allows high thermal dissipation. For a 2 cm×2 cm×2 cm three-dimensional vertical multijunction photovoltaic receiver billet receiving about 1000 suns or 400 watts, the maximum temperature at the billet entry surface U using the teachings of the instant invention is 122 C. As those skilled in the mechanical arts can appreciate, mating separable portions do not have to symmetric, equally sized, or mating at a midpoint or a set plane.

Now referring to FIG. 11, the oblique partial cut-out surface view similar to that shown in FIG. 10, is shown, with the illustrative three-dimensional photovoltaic receiver billet removed for clarity, showing the illustrative first heat sink surface H1 on the heat sink holding structure 1 able to conduct thermal flow T and provide an optoelectronic anode feed, shown both at anode A and ANODE.

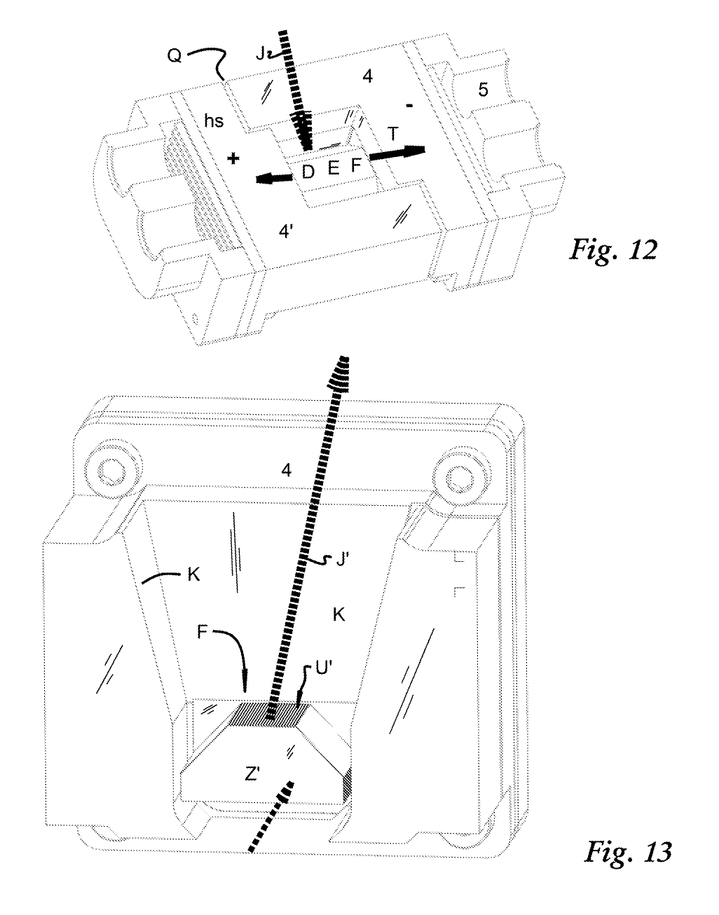

Now referring to FIG. 12, the oblique partial cut-out surface view of a complete optoelectronic holding structure 101 is shown according to the invention, showing joined together separable heat sink holding structure mating portions 4 and 4′ that are mutually electrically isolated, with an illustrative beam J impinging upon a three-dimensional optoelectronic device billet, which generally can be any of three-dimensional optoelectronic device billet D, three-dimensional photovoltaic receiver billet E, or a three-dimensional optoelectronic output device billet F which is capable of light output, such as a laser diode (outgoing beam not shown). This complete optoelectronic holding structure 101 can be mounted on a terrestrial or space vehicle or any desired target to which one desires to transmit power and/or communication signals.

Now referring to FIG. 13, an oblique partial cut-out surface view similar to that shown in FIG. 9 is shown, with an illustrative three-dimensional optoelectronic output device billet F that can produce an output beam illustratively shown when thermally and optoelectronically interfaced using the teachings of the instant invention using a heat sink holding structure and first and second heat sink surfaces H1 and H2 (not explicitly shown). In this way, an output beam, such as a communications beam, possibly originating from a three-dimensional optoelectronic device billet otherwise receiving beam energy, can be produced, such as for communication purposes with an entity possibly engaged in energy transfer. Outgoing beam J′ is shown emerging from exit surface U′ of three-dimensional optoelectronic output device billet F. Three-dimensional optoelectronic output device billet F can comprise known output devices such as any light-emitting diode, a solid state diode laser, a three-dimensional laser, a vertical-external-cavity surface-emitting-laser, or a vertical cavity surface-emitting laser, or future devices not yet contemplated.

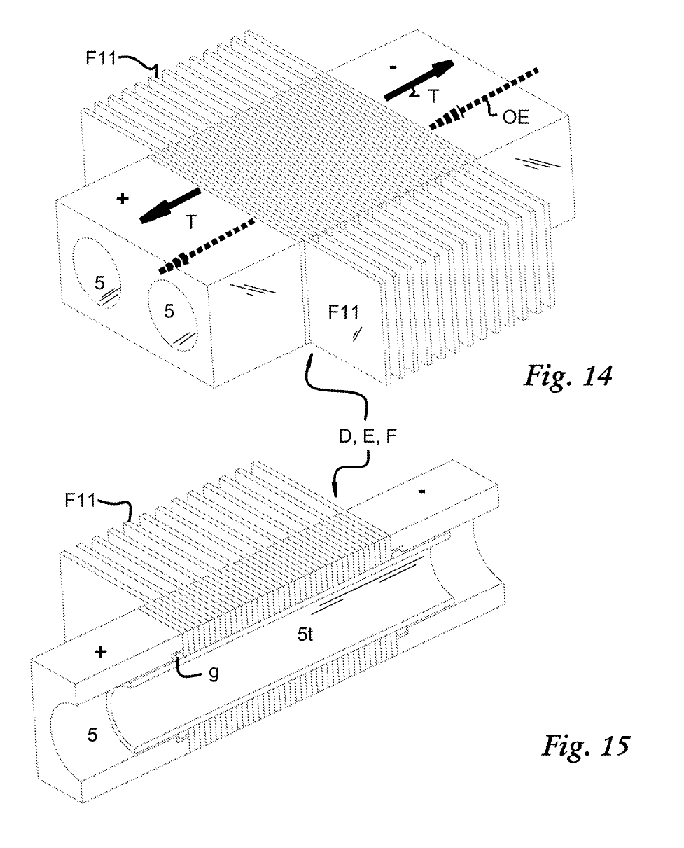

Now referring to FIGS. 14-15, oblique partial cut-out surface views of a three-dimensional optoelectronic device billet according to the invention are shown, with illustrative internal and external cooling systems depicted. In FIG. 14, a three-dimensional optoelectronic device billet is shown at the center of the structure shown, with thermal flow T and optoelectronic feeds as shown, establishing a negative anode feed and a positive cathode feed. In this alternate embodiment, protruding extended portions F11 are shown emerging from the three-dimensional optoelectronic device billet D, three-dimensional photovoltaic receiver billet E, or three-dimensional optoelectronic output device billet F. Protruding extended portions F11 can comprise metal slats or actual extended photovoltaic cell portions and can add thermal outflow, allowing dissipation of thermal energy via conduction transfer, convection transfer, or radiational transfer. In FIG. 15, a cutaway is shown of a internal cooling passage 5, showing an alternate preferred embodiment whereby a preferably non-electrically conducting cooling fluid is conveyed through a cooling pipe 5t which is secured to internal cooling passage 5 via a gasket g and surrounding structure.

In the optoelectronic feeds as shown, it is not strictly necessary to have an electrical feed, as an alternative optical feed can be used, such as for optical transducers, optical devices and the like. A ruby crystal conveying high intensity light can be used as a billet and the light can be conveyed via an optoelectronic feed as taught herein, and used or converted using structures or components not explicitly shown.

The heat sink holding structure 1 of the invention can be fabricated from solid copper, such as a 5×5×5 cm block. The invention as described can be used to allow optical refueling of electric platforms such as MUAVs airships, robotic exploration vehicles and other remote vessels.

Waveguide surfaces such as the surface of receiver waveguide K or the surfaces of the heat sink holding structures can be treated to form surface coatings that are designed to meet engineering objectives for various wavelengths of anticipated incident beams, including transparency, surface adhesion, high thermal conductivity and matched thermal expansion. The atomic layer deposition (ALD) process can be used to form such coatings, as is known in the surface treatment arts, and can comprise Al2O3, or AIN, which can act as a heat spreader. Other known oxides and alloys can be used. In this way, many components can be made from copper or other inexpensive materials, yet achieve specialized objectives.

In addition, wafers can include advanced SiC (silicon carbide) wafers, such as made by Dow Corning, Midland, Mich., USA. As conventional silicon approaches physical limits, materials sourcing has evolved and high-crystal quality silicone carbide (SiC) wafers can offer advantageous properties, resulting in wider electronic band gaps, high overall efficiencies, and higher thermal conductivity. This is attractive to many industries, including manufacturers of diodes and photovoltaic receivers and cells.

The instant teachings can be used in many different ways as those skilled in the art can appreciate. Generally a method is obtained using these teachings to allow establishing a thermal and electromagnetic interface with a three-dimensional optoelectronic device billet, by surrounding at least partially said three-dimensional optoelectronic device billet with a heat sink holding structure 1, communicating thermally with two opposing first and second billet surfaces Z, and Z′ on the three-dimensional optoelectronic device billet using the heat sink holding structure, and communicating optoelectronically with the three-dimensional optoelectronic device billet, and this can include use of an anode and a cathode. This can be applied to three-dimensional photovoltaic receiver billet E, via separate corresponding polarity ohmic contacts (+ and −) with each of the opposing first and second billet surfaces Z and Z′. The receiver waveguide K can be used to provide channeling, homogenizing, concentrating, and intensifying of the high intensity beam J, using the receiver waveguide proximate the three-dimensional photovoltaic receiver billet. A communications protocol can be applied to the high intensity beam J. A similar method can be applied to a three-dimensional optoelectronic output device billet F, and a an outgoing beam J′ produced can be modulated according to any known communications protocol.

What results from applying the teachings of the invention is a deep 3 dimensional, shaped structure, that when mounted and attached on the ends of an optoelectronic array can transfer large amounts of heat to the cooling structure (heat sink holding structure) described. With the VMJ (vertical multijunction) cell junctions parallel to the heat sink holding structure, requiring no electrical insulation, thermal transfer essential to high intensity operation is maximized.

As those skilled in the art can contemplate, the receivers shown here can be orientable, transferable and shielded when necessary by a moving cover or canopy. Any known communcation protocol can be used in conjunction with any incoming beam J or outgoing beam J′.

Those skilled in the engineering arts will appreciate that many possible schemes are permitted using the elements and teachings of the instant invention.

Other optical elements can be interposed between the elements of the appended claims without departing from the scope of the invention, as those skilled in the art can add desired functional steps or elements to serve needed ends in a particular application.

For example, components can be added, such as frequency discriminators such as a cold mirrors, etc. Curved or other focusing geometries can be employed in lieu of some of the planar surfaces illustratively depicted.

All of the elements as taught and claimed can be under an enclosure, lens, canopy, fluid or light-transmitting body without departing from the scope of the invention, as those skilled in the art may elect to protect, amplify, modify, or create in an alternative fashion energy conversion of high intensity light as taught in this disclosure.

There is obviously much freedom to exercise the elements or steps of the invention.

The description is given here to enable those of ordinary skill in the art to practice the invention. Many configurations are possible using the instant teachings, and the configurations and arrangements given here are only illustrative.

Those with ordinary skill in the art will, based on these teachings, be able to modify the invention as shown.

The invention as disclosed using the above examples may be practiced using only some of the optional features mentioned above. Also, nothing as taught and claimed here shall preclude addition of other reflective structures or optical elements.

Obviously, many modifications and variations of the present invention are possible in light of the above teaching. It is therefore to be understood that, within the scope of the appended claims using the Definitions given above, the invention may be practiced otherwise than as specifically described or suggested here.

We claim:

1. An optoelectronic holding structure (101) for receiving and communicating with a three-dimensional optoelectronic device billet (D, E, F), said optoelectronic holding structure comprising:
a heat sink holding structure (1) so formed, sized, shaped, and positioned to surround at least partially said three-dimensional optoelectronic device billet, said three-dimensional optoelectronic device billet comprising two opposing first and second billet surfaces (Z, Z′);
said heat sink holding structure further formed to comprise opposing first and second heat sink surfaces (H1, H2) so sized, shaped, positioned and oriented to be in direct thermal communication with said three-dimensional optoelectronic device billet at least partially via contact with some portion of a corresponding one of said opposing first and second billet surfaces;
said heat sink holding structure additionally so formed to comprise at least one optoelectronic feed (OE) in optoelectronic communication with said three-dimensional optoelectronic device billet.

2. The optoelectronic holding structure for receiving and communicating with the three-dimensional optoelectronic device billet of claim 1, wherein said optoelectronic feed comprises an electrical feed of at least one of an anode and a cathode in corresponding electrical communication with said three-dimensional optoelectronic device billet.

3. The optoelectronic holding structure for receiving and communicating with the three-dimensional optoelectronic device billet of claim 1, wherein said optoelectronic feed comprises an electrical feed with at least a portion of said first heat sink surface comprising one of an anode and a cathode; and at least a portion of said second heat sink surface comprising the other one of said anode and said cathode; said anode and said cathode each formed to be in corresponding electrical communication with said three-dimensional optoelectronic device billet.

4. The optoelectronic holding structure for receiving and communicating with the three-dimensional optoelectronic device billet of claim 1, wherein said heat sink holding structure comprises first and second at least somewhat mating separable portions (4, 4′), each so formed, sized and shaped to be proximate said opposing first and second heat sink surfaces, respectively.

5. The optoelectronic holding structure for receiving and communicating with the three-dimensional optoelectronic device billet of claim 4, wherein the first and second at least somewhat mating separable portions of said heat sink holding structure are so formed and positioned to be substantially electrically insulated from one another via at least one of an air gap, a fluid gap, and an insulator.

6. The optoelectronic holding structure for receiving and communicating with the three-dimensional optoelectronic device billet of claim 1, wherein said heat sink holding structure further comprises a receiver waveguide (K) formed proximate an entry side (U) of said three-dimensional optoelectronic device billet.

7. The optoelectronic holding structure for receiving and communicating with the three-dimensional optoelectronic device billet of claim 1, wherein said heat sink holding structure is so formed to comprise at least one internal cooling passage (5) formed to allow fluid heat transfer with at least one of said first and second heat sink surfaces.

8. The optoelectronic holding structure for receiving and communicating with the three-dimensional optoelectronic device billet of claim 1, wherein said heat sink holding structure is so formed and shaped to allow at least one of access to at least one internal cooling passage formed inside said three-dimensional optoelectronic device billet to allow fluid heat transfer with said billet, and thermal access to protruding extended portions (F11) of the billet so formed to dissipate thermal energy via any of conduction transfer, convection transfer, and radiational transfer.

9. The optoelectronic holding structure for receiving and communicating with the three-dimensional optoelectronic device billet of claim 1, wherein said heat sink holding structure is so formed to allow beam access to said three-dimensional optoelectronic device billet.

10. The optoelectronic holding structure for receiving and communicating with the three-dimensional optoelectronic device billet of claim 1, wherein said three-dimensional optoelectronic device billet comprises at least one of a photovoltaic receiver and a vertical multijunction photovoltaic receiver (VMJ).

11. The optoelectronic holding structure for receiving and communicating with the three-dimensional optoelectronic device billet of claim 1, wherein said heat sink holding structure is so formed to allow beam access to said three-dimensional optoelectronic device billet, and receiving of at least one of a multi-directional input beam spanning two orthogonal directions and a multi-directional input beam in a receptor plane (W) spanning more than two orthogonal directions.

12. A photovoltaic receiver system for receiving a high intensity beam, said photovoltaic receiver system comprising:
a three-dimensional photovoltaic receiver billet (E) comprising opposing first and second billet surfaces (Z, Z′);
an optoelectronic holding structure (101) for receiving and communicating with the three-dimensional photovoltaic receiver billet, said optoelectronic holding structure further comprising a heat sink holding structure (1) so formed, sized, shaped, and positioned to surround at least partially said three-dimensional photovoltaic receiver billet;
said heat sink holding structure further formed to comprise opposing first and second heat sink surfaces (H1, H2) each so sized, shaped, positioned and oriented to be in direct thermal communication with said three-dimensional photovoltaic receiver billet at least partially via contact with some portion of a corresponding one of said opposing first and second billet surfaces;
said heat sink holding structure additionally so formed to comprise an anode (A) and a cathode (C) each so positioned and formed to allow ohmic contact with a corresponding one of said opposing first and second billet surfaces.

13. The photovoltaic receiver system for receiving a high intensity beam of claim 12, wherein said anode and said cathode are each formed on a corresponding one of said first and second heat sink surfaces.

14. The photovoltaic receiver system for receiving a high intensity beam of claim 12, wherein said heat sink holding structure comprises first and second at least somewhat mating separable portions (4, 4′), each so formed, sized and shaped to be proximate said opposing first and second heat sink surfaces, respectively.

15. The photovoltaic receiver system for receiving a high intensity beam of claim 14, wherein the first and second at least somewhat mating separable portions of said heat sink holding structure are so formed and positioned to be substantially electrically insulated from one another via at least one of an air gap, a fluid gap, and an insulator.

16. The photovoltaic receiver system for receiving a high intensity beam of claim 12, wherein said heat sink holding structure further comprises a receiver waveguide (K) formed proximate an entry side (U) of said three-dimensional photovoltaic receiver billet.

17. The photovoltaic receiver system for receiving a high intensity beam of claim 12, wherein said heat sink holding structure is so formed to comprise at least one internal cooling passage (5) formed to allow fluid heat transfer with at least one of said first and second heat sink surfaces.

18. The photovoltaic receiver system for receiving a high intensity beam of claim 12, wherein said heat sink holding structure is so formed and shaped to allow at least one of access to at least one internal cooling passage formed inside said three-dimensional photovoltaic receiver billet to allow fluid heat transfer with said billet, and thermal access to protruding extended portions (F11) of the billet so formed to dissipate thermal energy via any of conduction transfer, convection transfer, and radiational transfer.

19. The photovoltaic receiver system for receiving a high intensity beam of claim 12, wherein said heat sink holding structure is so formed to allow beam access to said three-dimensional photovoltaic receiver billet.

20. The photovoltaic receiver system for receiving a high intensity beam of claim 12, wherein said three-dimensional photovoltaic receiver billet comprises a vertical multijunction photovoltaic receiver (VMJ).

21. The photovoltaic receiver system for receiving a high intensity beam of claim 12, wherein said heat sink holding structure is so formed to allow beam access to said three-dimensional photovoltaic receiver billet and receiving of at least one of a multi-directional input beam spanning two orthogonal directions and a multi-directional input beam in a receptor plane (W) spanning more than two orthogonal directions.

22. A thermal and electrical interface for a high intensity optoelectronic output device, said thermal and electrical interface comprising:
a three-dimensional optoelectronic output device billet (F) comprising opposing first and second billet surfaces (Z, Z′);
an optoelectronic holding structure (101) forthermal and electrical communication with the three-dimensional optoelectronic output device billet, said optoelectronic holding structure further comprising a heat sink holding structure (1) so formed, sized, shaped, and positioned to surround at least partially said three-dimensional optoelectronic output device billet;
said heat sink holding structure further formed to comprise opposing first and second heat sink surfaces (H1, H2) each so sized, shaped, positioned and oriented to be in direct thermal communication with said three-dimensional optoelectronic output device billet at least partially via contact with some portion of a corresponding one of said opposing first and second billet surfaces;
said heat sink holding structure additionally so formed to comprise an anode (A) and a cathode (C) each so positioned and formed to allow ohmic contact with a corresponding one of said opposing first and second billet surfaces.

23. The thermal and electrical interface for a high intensity optoelectronic output device of claim 22, wherein said anode and said cathode are each formed on a corresponding one of said first and second heat sink surfaces.

24. The thermal and electrical interface for a high intensity optoelectronic output device of claim 22, wherein said heat sink holding structure comprises first and second at least somewhat mating separable portions (4, 4′), each so formed, sized and shaped to be proximate said opposing first and second heat sink surfaces, respectively.

25. The thermal and electrical interface for a high intensity optoelectronic output device of claim 24, wherein the first and second at least somewhat mating separable portions of said heat sink holding structure are so formed and positioned to be substantially electrically insulated from one another via at least one of an air gap, a fluid gap, and an insulator.

26. The thermal and electrical interface for a high intensity optoelectronic output device of claim 22,
wherein said heat sink holding structure further comprises a receiver waveguide (K) formed proximate an entry side (U) of said three-dimensional optoelectronic output device billet.

27. The thermal and electrical interface for a high intensity optoelectronic output device of claim 22, wherein said heat sink holding structure is so formed to comprise at least one internal cooling passage (5) formed to allow fluid heat transfer with at least one of said first and second heat sink surfaces.

28. The thermal and electrical interface for a high intensity optoelectronic output device of claim 22, wherein said heat sink holding structure is so formed and shaped to allow at least one of access to at least one internal cooling passage formed inside said three-dimensional optoelectronic output device billet to allow fluid heat transfer with said billet, and thermal access to protruding extended portions (F11) of the billet so formed to dissipate thermal energy via any of conduction transfer, convection transfer, and radiational transfer.

29. The thermal and electrical interface for a high intensity optoelectronic output device of claim 22, wherein said heat sink holding structure is so formed to allow beam access to said three-dimensional optoelectronic output device billet.

30. The thermal and electrical interface for a high intensity optoelectronic output device of claim 22, wherein said three-dimensional optoelectronic output device billet comprises at least one of a light-emitting diode, a solid state diode laser, a three-dimensional laser, and a vertical-external-cavity surface-emitting-laser, and a vertical cavity surface-emitting laser.

31. The thermal and electrical interface for a high intensity optoelectronic output device of claim 22, wherein said heat sink holding structure is so formed to allow beam access to said three-dimensional optoelectronic output device billet, and receiving of at least one of a multi-directional input beam spanning two orthogonal directions and a multi-directional input beam in a receptor plane (W) spanning more than two orthogonal directions.

32. A method for establishing a thermal and electromagnetic interface with a three-dimensional optoelectronic device billet (D, E, F), said method comprising:
[1] surrounding at least partially said three-dimensional optoelectronic device billet with a heat sink holding structure (1);
[2] communicating thermally with two opposing first and second billet surfaces (Z, Z′) on said three-dimensional optoelectronic device billet with said heat sink holding structure via at least partial direct thermal contact therebetween; and
[3] communicating optoelectronicallywith said three-dimensional optoelectronic device billet

33. A method for receiving and photovoltaic conversion of a high intensity beam (J), said method comprising:
[1] receiving said high intensity beam on a three-dimensional photovoltaic receiver billet (E) that comprises opposing first and second billet surfaces (Z, Z′) and that is at least partially surrounded by a heat sink holding structure (1);
[2] communicating thermally with the two opposing first and second billet surfaces on said three-dimensional photovoltaic receiver billet using said heat sink holding structure via at least partial direct thermal contact therebetween; and
[3] communicating electrically via said three-dimensional photovoltaic receiver billet via separate corresponding polarity ohmic contacts with each of said opposing first and second billet surfaces.

34. The method for receiving and photovoltaic conversion of a high intensity beam of claim 33, additionally comprising at least one of channeling, homogenizing, concentrating, and intensifying said high intensity beam using a receiver waveguide proximate said three-dimensional photovoltaic receiver billet.

35. The method for receiving and photovoltaic conversion of a high intensity beam of claim 33, wherein said high intensity beam is modulated according to a communications protocol.

36. A method for operating a three-dimensional optoelectronic output device billet (F) to produce a beam (J), said method comprising:
[1] communicating electricallywith said three-dimensional optoelectronic output device billet via separate corresponding polarity ohmic contacts with each of opposing first and second billet surfaces (Z, Z′) located thereupon;
[2] communicating thermally with the two opposing first and second billet surfaces on said three-dimensional optoelectronic output device billet using a heat sink holding structure via at least partial direct thermal contact therebetween; and
[3] allowing said beam produced by said three-dimensional optoelectronic output device billet to pass outward from said heat sink holding structure.

37. The method for operating a three-dimensional optoelectronic output device billet of claim 36, additionally comprising at least one of channeling, homogenizing, concentrating, and intensifying said high intensity beam using a receiver waveguide proximate said three-dimensional optoelectronic output device billet.

38. The method for operating a three-dimensional optoelectronic output device billet of claim 36, wherein said beam is modulated according to a communications protocol.
